(19) United States
(12) Patent Application Publication
(10) Pub. No.: US 2024/0377465 A1
(43) Pub. Date: Nov. 14, 2024

(54) METHOD FOR PREVENTING DAMAGE TO A FUEL CELL STACK

(71) Applicant: Robert Bosch GmbH, Stuttgart (DE)

(72) Inventors: Achim Brenk, Kaempfelbach (DE); Bernd Becker, Stuttgart (DE); Joachim Schurr, Eschenbach (DE); Kai Wipplinger, Koengen (DE); Thomas Wuerzbach, Tamm (DE)

(21) Appl. No.: 18/688,817

(22) PCT Filed: Jul. 11, 2022
(86) PCT No.: PCT/EP2022/069266

§ 371 Date: Mar. 4, 2024

(30) Foreign Application Priority Data
Sep. 3, 2021 (DE) 10 2021 209 686.7

(51) Int. Cl. G01R 31/3835; G01R 31/396; H01M 8/04537; H01M 8/10

(52) U.S. Cl. CPC G01R 31/3835; G01R 31/396; H01M 8/04559; H01M 2008/1095; H01M 2250/20

(57) ABSTRACT

The invention relates to a method for detecting a harmful cell voltage (U) of a cell region of a fuel cell stack, wherein the noise (201, 202) of a signal (200) of the cell voltage (U) is determined by means of a cell monitoring process corresponding individually to the fuel cell stack in order to detect harmful cell voltage (U), and a change, in particular a reduction, of the noise (201, 202) with respect to a characteristic noise (201, 202) of the cell voltage (U) is detected as a used signal for a harmful cell voltage (U).

### BACKGROUND

The invention relates to a method for detecting a harmful cell voltage of a cell region of a fuel cell stack. The invention also relates to a cell monitoring process, a fuel cell stack, a fuel cell unit and a fuel cell system, in particular for a fuel cell vehicle.

In a low-temperature polymer electrolyte fuel cell of a fuel cell unit, e.g. a fuel cell system of a fuel cell vehicle, an electrochemical conversion of two reactants of two operating media into electrical energy and heat takes place. The fuel cell comprises at least one membrane electrode assembly (MEA). As a rule, the fuel cell is designed with a plurality of membrane electrode assemblies arranged in a stack and bipolar plates arranged between them (fuel cell stack).

To monitor, control and/or regulate a fuel cell stack, it is advantageous to know not only the parameters of the entire fuel cell stack, but also at least one of each individual fuel cell (single cell) within the fuel cell stack. So-called CVM systems (cell monitoring process, CVM: Cell Voltage Monitor(ing)) are used for this purpose. Since even the slightest damage in a single cell can grow exponentially in size, it is very important to recognize a malfunction of an affected single cell at an early stage in order to be able to counteract further damage to this single cell.

### SUMMARY

It is a task of the invention to provide a method for monitoring cells in a fuel cell stack. The cell monitoring method is intended to enable early detection of imminent damage to a cell section of the fuel cell stack, i.e. a single cell and/or a group of cells.

The problem of the invention is solved by a method for detecting a damaging cell voltage of at least one cell region of a fuel cell stack; and by means of a cell monitoring process, a fuel cell stack, a fuel cell unit or a fuel cell system, in particular for a fuel cell vehicle. Advantageous further developments, additional features and/or advantages of the invention are apparent from the dependent claims and the following description.

In the method according to the invention, a noise of a signal of the cell voltage is determined by means of a cell monitoring process corresponding individually to the fuel cell stack for detecting the damaging cell voltage, wherein a change, in particular a reduction, of the noise compared to a characteristic noise of the cell voltage is detected as a useful signal for a harmful cell voltage. A cell region comprises 1 to n single cells, i.e. a single single cell, a cell group, a cell cluster, etc.

A cell group or cell cluster in each case comprises a plurality of single cells. The single cells of a cell group are designed as a small stack in the fuel cell stack, wherein one single cell directly follows another single cell in this small stack. In a cell cluster, on the other hand, there is at least one single cell that is not directly adjacent to another immediately neighboring single cell of this cell cluster (there is at least one single cell in between that does not belong to this cell cluster). In the case of cell clusters, for example, it is possible for a single cell to belong to a plurality of cell clusters. Further, at least one single cell can be omitted from a cell cluster, analogous to cell groups among each other, which together also do not have to constitute the entire fuel cell stack.

When determining the noise, it is not possible to determine the cell voltage itself for this method. Alternatively, the cell voltage of the at least one cell region for this method can also be determined, in particular measured, by means of the individual cell monitoring process. The characteristic (comparative) noise can be a typical noise of this or at least one comparable fuel cell stack determined in advance or currently. This typical noise can be determined empirically in advance, either independently or depending on the cell voltage level.

The characteristic (comparative) noise can be characterized by relative maxima and minima with respect to the cell voltage signal when it occurs undisturbed. The undisturbed occurrence of the characteristic noise should of course mean that the noise is not cut off due to a one-sided power supply, for example. This means, for example, that the characteristic noise can be determined at sufficiently high positive cell voltages. In particular, this ratio can be 1:1, i.e. upward deflections of the signal and downward deflections of the signal balance each other out. Other ratios are of course also possible, i.e. the characteristic (comparative) noise can be characterized by a ratio around the cell voltage signal if it occurs undisturbed.

A constant, in particular characteristic, noise of the cell voltage signal can be an indication of a correct operating state of the cell region. This means that a cell voltage with a constant noise is detected as a non-harmful cell voltage according to this method. A reduction in the noise of the cell voltage signal can be an indication of a falling cell voltage. This means that a cell voltage with a reducing noise is detected according to this method in such a way that a potentially harmful cell voltage can or will occur if the noise of the cell voltage continues to be reduced.

An increase in the noise of the cell voltage signal can be a sign of increasing cell voltage. This means that a cell voltage with increasing noise is detected according to this method in such a way that no potentially harmful cell voltage can or will occur if the noise of the cell voltage continues to increase. If a changed, in particular characteristic, noise remains essentially the same, the direction in which the noise develops over time (reduction, remaining the same or increase) must be closely observed.

The change (reduction, increase) in the noise can be detected by a significant change in a spread and/or a normal distribution of the noise over the cell voltage. This can also be detected by the occurrence of cell voltages of zero or neutral cell voltages. This can also be detected by a ratio of time components of the cell voltages greater than zero or the neutral cell voltage, and of zero or the neutral cell voltage. This also means, of course, that the characteristic noise of the cell voltage no longer occurs here.

The following relative strengths, characteristics, changes etc. of the noise of the cell voltage signal are of course related to each other and constitute each other. In this case, a noise that has changed in nature means a noise such that, starting from the cell voltage signal, it now essentially points in one direction, i.e. either in the direction of a lower cell voltage or, in particular, in the direction of a higher cell voltage (see FIG. 3 regions III and IV). This also means that approx. half of the noise is cut off.

Determining (see FIG. 3 region II) of a cell voltage that is problematic for the cell region or an approximation to a neutral cell voltage of a single cell can be detected by a slightly or significantly changed, in particular a slightly to significantly reduced, noise. Here, reduced noise can be detected in a range below (in the direction of lower or less positive cell voltages) than in the same range above (in the direction of higher or more positive cell voltages) the cell voltage signal. Furthermore, a fully developed characteristic noise can be detected in a range above the cell voltage signal. This means, for example, that the peaks of the noise below the cell voltage signal are partially cut off, wherein the peaks of the noise above the cell voltage signal are present undiminished.

Determining (see FIG. 3 region III) of a cell voltage that can be harmful to the cell region or a neutral cell voltage of a single cell in the cell region can be detected by a significantly altered noise or a noise that has changed in its nature, and in particular a significantly reduced noise. Preferably, hardly any or no noise can be detected in a range below (in the direction of lower or less positive cell voltages) the cell voltage signal. Furthermore, a completely pronounced or slightly reduced characteristic noise can be detected in a range above (in the direction of higher or more positive cell voltages) the cell voltage signal. This means, for example, that the peaks of the noise below the cell voltage signal are almost completely to completely cut off, wherein the peaks of the noise above the cell voltage signal are present undiminished.

Determining (see FIG. 3 region IV) of a cell voltage that is harmful to the cell region or an inverted cell voltage of a single cell in the cell region can be detected by a noise that is completely changed in its nature and in particular greatly reduced. No noise can be detected in a range below (in the direction of lower or less positive cell voltages) the cell voltage signal. Furthermore, a slightly or significantly reduced characteristic noise can be detected in a range above (in the direction of higher or more positive cell voltages) the cell voltage signal. In addition, little or preferably no noise can be detected in a range below the cell voltage signal. This means, for example, that the peaks of the noise below the cell voltage signal are completely cut off, wherein the peaks of the noise above the signal are completely reduced to almost non-existent.

The cell voltage of the cell region can be calculated by a ratio of the temporal proportions of positive cell voltages to the simultaneous proportions of neutral cell voltages. If the ratio here is 50:50, for example, the neutral cell voltage is present, i.e. the relevant cell region adds a cell voltage of 0V to the fuel cell stack. If more than 50% of the cell voltages are greater than zero (i.e. the proportion of the cell voltages of zero is less than 50%), this is a positive cell voltage. If less than 50% of the cell voltages are greater than zero (i.e. the proportion of cell voltages of zero is greater than 50%), this is a negative cell voltage.

The cell monitoring process can be used to determine a current cell voltage of the at least one cell region, wherein a noise of this current cell voltage is determined to detect the harmful cell voltage. In other words, the method is designed as a method for detecting a substantially currently harmful cell voltage of at least one cell region of the fuel cell stack. Furthermore, alternatively or additionally, an averaged cell voltage of the at least one cell region can be determined by means of the cell monitoring process by means of a sampling frequency in a sampling interval, wherein a noise of the averaged cell voltage in the sampling interval is determined to detect the harmful averaged cell voltage. In other words, the method is designed as a method for detecting a harmful level of the cell voltage of at least one cell region of the fuel cell stack.

To detect the harmful cell voltage, the noise of the current or averaged cell voltage can be compared with at least one previously determined noise of a current or averaged cell voltage. Empirical data from at least one comparable fuel cell stack from tests, in particular on test benches, can also be included in the method. Furthermore, empirical data from a plurality of comparable fuel cell stacks from their operation (this can also include the conditioning phases of the fuel cell stacks) can be included in the method. In addition, empirical data from the operation of this fuel cell stack can be included in the method.

The cell monitoring process can have or comprise a single-sided power supply, which only provides a positive voltage for measuring the cell voltages. The cell monitoring process cannot have or comprise a power supply that could provide a negative voltage for measuring the cell voltages. This means that the power supply of the cell monitoring process is not designed as a symmetrical power supply that could supply the cell monitoring process with positive and negative voltages. A neutral voltage can be provided to your microprocessors to measure the cell voltages by the cell monitoring process.

### BRIEF DESCRIPTION OF THE DRAWINGS

The invention is explained in more detail below with reference to the attached schematic drawing, which is not to scale, by means of exemplary embodiments. In the invention, a feature can be positive, i.e., present, or negative, i.e., absent. In this specification, a negative feature is not explicitly explained as a feature unless the invention emphasizes that it is absent, i.e., the invention actually made and not one constructed by the prior art consists in omitting this feature. The absence of a feature (negative feature) in an exemplary embodiment shows that the feature is optional. The figures (Fig.) in the drawing are merely examples:

FIG. 1 shows a schematic overview of a device for monitoring cell voltages, including actual cell monitoring process of a fuel cell stack of a fuel cell unit,

FIG. 2 shows a comparison of two voltage curves measured by the cell monitoring process for any single cell in the fuel cell stack, with a symmetrical (top) and a single-sided (bottom) power supply to the cell monitoring process,

FIG. 3 in a representation analogous to FIG. 2 below, but strongly idealized and enlarged, a diagram of a noisy voltage curve of any single cell of a fuel cell stack around a neutral voltage of the single cell, and

FIG. 4 is a diagram illustrating embodiments of a method according to the invention for detecting a harmful cell voltage of at least one cell region of a fuel cell stack.

### DETAILED DESCRIPTION

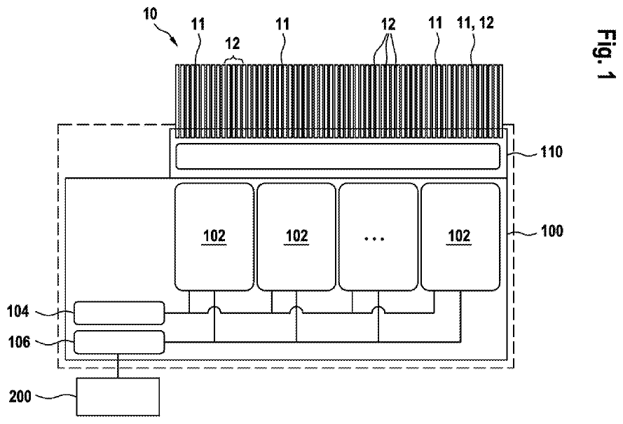

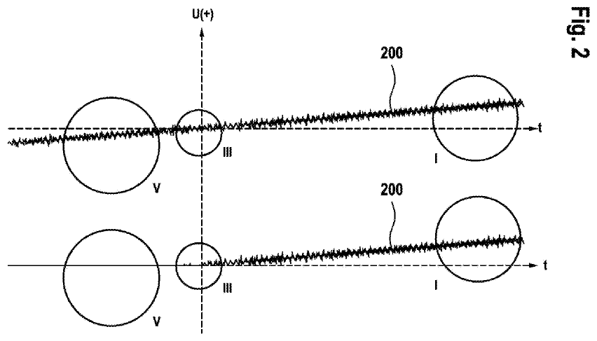

The invention is explained in more detail with reference to embodiments of a method for detecting a harmful cell voltage U (see FIGS. 2 through 4) of at least one cell region 12 (see above) of a fuel cell stack 10 (see FIG. 1) of a fuel cell unit for a low-temperature polymer electrolyte fuel cell system of a fuel cell vehicle, i.e. a motor vehicle having this fuel cell or this fuel cell system. Although the invention is described and illustrated in more detail by preferred embodiments, the invention is not limited by the disclosed exemplary embodiments. Other variations can be derived from this without leaving the scope of protection of the invention.

A fuel cell stack 10 (FIG. 1) consists of many single cells 11, which are electrically connected in clusters to form a larger network. For conditioning, monitoring, control and/or regulation etc. of the fuel cell stack 10 and its fuel cell system, it is advantageous to know not only operating parameters of the entire fuel cell stack 10, but also operating parameters of each cell region 12 and/or of each single cell 11 within the fuel cell stack 10. A cell monitoring process 100 (CVM) is used for this purpose, which serves to measure the electrical cell voltages U and/or other operating parameters of the cell regions 12 and/or the single cells 11 within the fuel cell stack 10.

The following explanations relate only to single cells 11 of the fuel cell stack 10, but are of course also applicable to cell regions 12 (see above) with a plurality of single cells 11. According to the invention, a previously empirically determined and/or a current behavior of such a cell region 12 can of course be included in an object of the invention if necessary.

In normal operation of the fuel cell stack 10, only positive cell voltages U occur within each single cell 11 (cell regions 12). If problems occur, e.g. when supplying the fuel cell stack 10 with fuel, a negative cell voltage U can also occur within a single cell 11. Negative cell voltages U lead within a very short time to damage to an ion exchange membrane of a relevant single cell 11 between two bipolar plates of the fuel cell stack 10, and thus to a rapid reduction in the service life of the single cell 11 and consequently also of the fuel cell stack 10.

For this reason, it is necessary to identify the cell voltages U of the fuel cell stack 10 in order to be able to react to emerging problems at an early stage. As soon as the cell voltage U of a single cell 11 falls below a predefined, still positive value, initial measures can be initiated to stabilize and/or raise the voltage level of the single cell 11 in question. If the cell voltage U continues to drop despite these measures and falls below a neutral cell voltage U in its position in the fuel cell stack 10, a safety or emergency shutdown of the relevant single cell 11 or the fuel cell stack 10 is carried out. For this reason, it is necessary that the cell monitoring process 100 can also measure negative cell voltages U.

To identify and measure the cell voltages U of the single cells 11, a plurality of microprocessors 102 (electronic component or sub-architecture) can be used, which have several channels for measuring several cell voltages U. A disadvantage of these microprocessors 102 is a so-called symmetrical power supply, which is required for the identification of negative or inverted cell voltages U. In order to measure a negative or inverted cell voltage U, a microprocessor 102 must also be supplied with a negative voltage in addition to a positive voltage U and the neutral voltage. If this is not supplied with a negative voltage, the lowest or first cell assigned to a microprocessor 102 cannot recognize negative or inverted cell voltages.

As there is no negative voltage available in the fuel cell vehicle, this can only be realized with a so-called symmetrical power supply and only with considerable effort and at high cost. In addition, the microprocessors 102, which are used to measure the negative or inverted cell voltages U, are also associated with additional costs compared to conventional voltage measurement chips.

Measuring the cell voltages U of the single cells 11 (cell regions 12) can help to ensure that problems with single cells 11 can be detected at an early stage and subsequently rectified. Since even the slightest damage to an ion exchange membrane increases in extent at an exponential rate, it is very important to recognize a malfunction of a single cell 11 at an early stage and to do something about it. Such damage is caused by negative or inverted cell voltages U. Since the identification and recognition of such cell voltages U using conventional methods is cost-intensive, a method is described which is also capable of detecting and, if necessary, measuring negative or inverted cell voltages using only a one-sided voltage measurement.

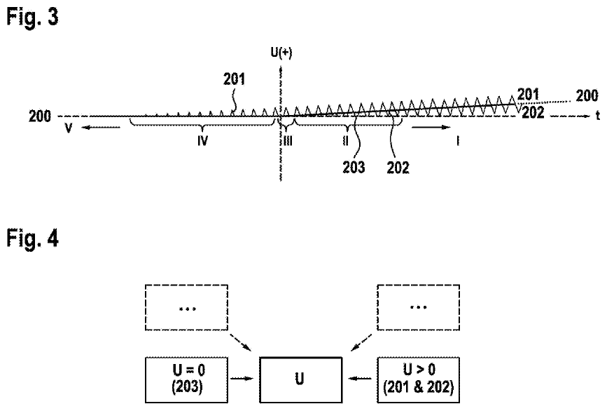

According to the invention, it is sufficient to measure only positive cell voltages U in order to detect problems or avoid damage to the single cells 11. This allows a much more cost-effective evaluation circuit for measuring the cell voltages U to be realized. If negative or inverted cell voltages U occur, a voltage value can no longer be measured but can be calculated. For this purpose, a method for evaluating the exclusively positive measured voltage values is presented, which is able to obtain clear conclusions about the indication of the cell voltages U only from a noise 201, 202 of the measured signals 200 (see FIGS. 2 and 3) cell voltages U and without measuring the negative or inverted cell voltages U. This means that only a single-sided power supply can be used. Nevertheless, a symmetrical power supply can also be used.

The fuel cell stack 10 (FIG. 1) has a plurality of single cells 11, which are arranged between bipolar plates of the fuel cell stack 10. The cell monitoring process 100 is electrically connected to the bipolar plates via a contacting unit 110 (CVP: Cell Voltage Pickup CVP, electromechanical voltage pickup including a respective communication connection (cable and plug connector)) and measures the cell voltages U of the single cells 11 or, analogously, of the cell regions 12.

In fuel cell stacks 10, voltage dips and even inverted voltage ratios can be observed. One cause can be an uneven distribution of a temperature or an uneven distribution of other parameters or boundary conditions. For example, an insufficient supply of an appropriate fuel, an oversupply of a gas that is no longer required and/or water vapor in a single cell 11 can result in the cell voltage U of this single cell 11 being outside, in particular below, its target range.

In order to recognize such conditions via an operating strategy and to be able to initiate countermeasures, it is necessary to measure the cell voltages U and to detect negative or inverted cell voltages. This can be demonstrated very well with measuring equipment, e.g. on a test bench, as symmetrical measurement of the cell voltage U is possible here. Typical values of single cells 11 of fuel cell stacks 10 and, in the present case, a characteristic noise 201, 202 of a cell voltage U of a single cell 11 of a fuel cell stack 10 can also be obtained individually or type-specifically in advance. This can occur over a comparatively wide range, i.e. from high positive to comparatively high negative values.

For the operation of a fuel cell stack 10 in a series application, this is often not possible for reasons of space and/or cost. In order to nevertheless exploit the potential of an operating strategy and/or diagnosis, the cell monitoring process 100 described here should only be able to measure one-sided cell voltages U from zero upwards. Cell voltages U less than zero or inverted cell voltages U cannot be measured, but can still be detected and, if necessary, calculated by means of the evaluation method described below. If a cell voltage U of the fuel cell stack 10 is measured close to the neutral voltage or exactly at the neutral voltage, this measured cell voltage U can be distinguished from a negative cell voltage U at a structure of a level of the noise 201, 202, see FIGS. 2 and 3.

In other words, according to the invention, a useful signal is generated from the noise 201, 202 of a signal 200 of the cell voltage U. The noise 201, 202 of the signal 200 is no longer exclusively a disturbance variable, but according to the invention enables a brief look into the future of a probable development of a cell voltage U of a single cell 11 of a fuel cell stack 10. And this is particularly in the direction of the neutral voltage, which is problematic for the single cell 11, and also in the direction of a highly problematic inverted voltage ratio.

The upper diagram in FIG. 2 shows a voltage measurement of a time-varying cell voltage (symmetrical power supply). The signals 200 of the cell voltage U comprise both a negative voltage range (below the t-axis in each case) and a positive voltage range (above the t-axis in each case) and are superimposed by a noise 201, 202 (see also FIG. 3). This represents a voltage measurement which is not limited to a purely positive measuring range.

The lower diagram in FIG. 2 represents a voltage measurement of a one-sided, i.e. asymmetrical, voltage measurement (one-sided power supply). Negative or inverted voltages U cannot be identified and are output as zero. Noise 201, 202 only occurs here in the direction of positive voltages (FIG. 3: item 201); noise 201, 202 in the negative voltage range (FIG. 3: item 202) does not occur due to the one-sided power supply. In principle, the noise 201, 202 does not occur below zero or the neutral voltage; i.e. with a maximum noise value downwards, this is cut off downwards starting at positive voltages U, which lie in this range in terms of magnitude (see FIG. 2 below and FIG. 3) (see FIG. 3, region II on the right).

The two regions I in FIG. 2 show measured signals 200 of a single cell 11 in the exclusively positive range of the cell voltages U, which are superimposed by a noise 201, 202. The two regions V in FIG. 2 represent measured signals 200 of a single cell 11, which lie in the clearly negative range of the cell voltages U. In the upper diagram in FIG. 2, an electronic system for voltage measurement can identify and measure a negative or inverted signal 200. In the lower diagram of FIG. 2, a much more cost-effective electronic system 102, (104), 106 with a single-sided power supply 104 was used, which can only detect positive voltage values, so that any negative or inverted cell voltage U that can actually be present on a single cell 11 can no longer be measured. Instead, the measured value of signal 200 with zero is always output for such actual values.

It can be clearly seen in FIG. 2 below (see also the idealized FIG. 3) that in the negative or inverted range of the voltages U, noise 201, 202 of the signal 200 can also not be identified by the cell monitoring process 100. Only thermal noise can still have an influence, but this is so small that it can no longer be identified by the cell monitoring process 100. The two regions V of FIG. 2 mark the clearly negative cell voltages U, the regions I of FIG. 2 mark the clearly positive cell voltages U. The regions III of FIG. 2 mark a signal detection of the cell monitoring process 100 in a transition region from measured positive to negative cell voltages U or vice versa. It can be clearly seen here that the noise 201, 202, which is superimposed on the signal 200 of the cell voltage U, can only be identified in the positive signal range, i.e. it also occurs in the measured signal 200. During the transition from a positive to a negative cell voltage U, the identified and measured noise 201, 202 decreases successively.

If the method is applied from the side of comparatively high positive cell voltages U in the direction of the neutral cell voltage U (i.e. from the right in FIGS. 2 and 3), those parts of an overall signal (signal 200 of the measured cell voltage U plus noise 201, 202) which (would) fall into the range of negative values of the cell voltages U due to the noise 201, 202 are no longer identified (FIG. 3: region II). If the signal 200 of the measured cell voltage U is (exactly or approximately) zero, the noise 201, (202) is only detected during (exactly or approximately) one half of the measured time, the other components of the overall signal are measured as zero (FIG. 3: region III). If the cell voltage U drops even further (FIG. 3: region IV), the temporal components of the noise 201 become smaller and smaller and the temporal components, which are identified as zero, increase continuously (FIG. 3: region IV through region V).

If a signal 200 of the cell voltages U to be measured, which is subject to noise 201, 202, lies in the range around the neutral cell voltage U (FIG. 3: region III), some of the measured values are not identified correctly when the cell voltages U are measured directly, as they lie below the neutral cell voltage U and therefore cannot be identified. Nevertheless, it is also possible to measure the cell voltages U in this voltage range (below the neutral cell voltage U, i.e. with negative or inverted cell voltages) without having to use a symmetrical voltage supply or a voltage measurement system that is also suitable for negative, i.e. inverted, cell voltages U.

Values of the cell voltages U which are (exactly or approximately) zero, i.e. correspond to the neutral cell voltage U, are characterized in that the time components at which the value zero (see FIG. 4:203, no more noise; and cf. FIG. 3) is measured and the time components at which a value above zero is measured due to the noise 201 (see FIG. 4: 201, noise occurs; and cf. FIG. 3) are (exactly or approximately) equal. For values of the cell voltages U that are greater than zero, the proportion of time at which values of zero are identified due to the one-sided power supply decreases, wherein values of the cell voltages U above zero are identified significantly more often in a comparison (FIG. 3: region II). For values of the cell voltages U in the negative range, the time components at which a zero is identified predominate over the time components with positive voltage values (FIG. 3: region IV).

A cell voltage U can now be calculated using a ratio, see FIG. 4, of the time components of the cell voltages U above zero (FIG. 4 right: U>0, noise 201, 202 occurs) and the time components of a cell voltage U of zero (FIG. 4 left: U=0, 203; no more noise 201, 202). This also makes it possible to measure cell voltages U in the negative voltage range without the measurement system being able to detect negative cell voltages U. Furthermore, a previously determined noise 201, 202 can be included in the detection of the harmful cell voltage U, which is shown as a dashed line in FIG. 4.

Extending the measuring range into a range of negative cell voltages U can require a reduction in the sampling frequency of the cell monitoring process 100 if comparatively accurate mean values are to be obtained. Since the exact cell voltages U result from a time ratio of the measured values, a plurality of measured values must be evaluated in order to obtain exact average values of the cell voltages U. However, this reduction in the sampling frequency can only be necessary in a narrow range around the neutral cell voltage U. For the remaining ranges of positive cell voltages U, a sampling rate can remain unchanged. This means that all controllers in normal operation of the fuel cell can access the previously usual performance of the measured values and are not affected by the reduction in the sampling rate.

In order to counteract an exponential increase in damage in the single cells 11 of a fuel cell stack 10, it is important to detect a malfunction of a single cell 11 very early and thus prevent damage in a nucleus. For this reason, the measured values of the single cells 11 or, analogously, of cell regions 12 are identified at a high frequency. This ensures that a malfunction is detected at an early stage. Depending on the number of single cells 11 or cell regions 12 within the fuel cell stack 10, many voltage measurement channels are required. By dispensing with a negative cell voltage measurement of the electronic system 102, (104), 106, a symmetrical and thus also galvanically isolated and consequently more complex symmetrical power supply can be dispensed with.

Although the cell monitoring process 100 cannot measure negative cell voltages U, it is still possible to detect and measure negative cell voltages U using the method for detecting a harmful cell voltage U (see also above). The advantage consists in a cost saving and a saving of installation space, which is achieved by a simpler circuit design of the electronic system 102, (104), 106; i.e. by dispensing with an electrically isolated and symmetrical power supply of the individual voltage measurement channels, as well as by the use of low-cost microprocessors 102 for voltage measurement.

1. A method for detecting a harmful cell voltage (U) of a cell region (12) of a fuel cell stack (10), the method comprising,
determining a noise (201, 202) of a signal 200 of the cell voltage via a cell monitoring process (100) corresponding individually to the fuel cell stack (10) for detecting the harmful cell voltage (U), and
determining a change of the noise (201, 202) with respect to a characteristic noise (201, 202) of the cell voltage (U) as a used signal for a harmful cell voltage (U).

2. The method according to claim 1,
wherein, when determining the noise (201, 202), the cell voltage (U) itself is not determined, or
the cell voltage (U) of the at least one cell region (12) is determined via the individual cell monitoring process (100).

3. The method according to claim 1, wherein:
a constant noise (201, 202) of the signal (200) of the cell voltage (U) is an indication of a correct operating state of the cell region (12),
a reduction in the noise (201, 202) of the signal (200) of the cell voltage (U) is an indication of a falling cell voltage (U), and/or
an increase in the noise (201, 202) of the signal (200) of the cell voltage (U) is an indication of an increasing cell voltage (U).

4. The method according to claim 1, wherein the change in noise (201, 202):
by a significant change in a spread and/or a normal distribution of the noise (201, 202) over the cell voltage (U),
by the occurrence of cell voltages (U) of zero (U=0) or neutral cell voltages (U=0), and/or
is detected by a ratio of time components of the cell voltages (U) greater than zero (U>0) or the neutral cell voltage (U>0), and of zero (U=0) or the neutral cell voltage (U>0).

5. The method according to claim 1, wherein determining of a cell voltage (U) problematic for the cell region (12) or an approximation to a neutral cell voltage (U) of a single cell (11) by (II):
a slightly or significantly altered noise (201, 202),
a reduced noise (201, 202) in a range below (202) than in the same range above (201) the signal (200) of the cell voltage (U), and/or
a fully developed characteristic noise (201) is detected in a range above (201) the signal (200) of the cell voltage (U).

6. The method according to claim 1, wherein determining of a cell voltage (U) which can be harmful to the cell region (12) or of a neutral cell voltage (U) of a single cell (11) in the cell region (12) is carried out by (III):
a significantly altered or changed in its nature,
no noise (201, 202) in a range below (202) the signal (200) of the cell voltage (U), and/or
a completely pronounced or slightly reduced characteristic noise (201) is detected in a range above (201) the signal (200) of the cell voltage (U).

7. The method according to claim 1, wherein determining of a cell voltage (U) harmful to the cell region (12) or an inverted cell voltage (U) of a single cell (11) in the cell region (12) is carried out by (IV):
a noise that is completely changed in its nature,
no noise (201, 202) in a range below (202) the signal (200) of the cell voltage (U),
a slightly or significantly reduced characteristic noise (201) in a range above (201) the signal (200) of the cell voltage (U), and/or
no noise (201) is detected in a range below (202) the signal (200) of the cell voltage (U).

8. The method according to claim 1, wherein the cell voltage (U) of the cell region (12) is calculated by a ratio of the temporal proportions of positive cell voltages (U) with respect to the simultaneous proportions of neutral cell voltages (U).

9. The method according to claim 1, wherein a current cell voltage (U) of the at least one cell region (12) is determined by means of the cell monitoring process (100), and a noise (201, 202) of this current cell voltage (U) is determined for detecting the harmful cell voltage (U), and/or
an averaged cell voltage (U) of the at least one cell region (12) is determined by means of the cell monitoring process (100) by means of a sampling frequency in a sampling interval, and a noise (201, 202) of the averaged cell voltage (U) in the sampling interval is determined for detecting the harmful averaged cell voltage (U).

10. The method according to claim 1, wherein, for detecting the harmful cell voltage (U), the noise (201, 202) of the current or the averaged cell voltage (U) is compared with at least one noise (201, 202) of a current or averaged cell voltage (U) determined previously in time.

11. The method according to claim 1, wherein:
the cell monitoring process (100) has/comprises a voltage supply on one side only, which provides only a positive voltage for measuring the cell voltages (U),
the cell monitoring process (100) does not have/comprehend a power supply which could provide a negative voltage for measuring the cell voltages (U), and/or
a neutral voltage is made available to its microprocessors (102) by the cell monitoring process (100) for measuring the cell voltages (U).

12. A cell monitoring process (100), fuel cell stack (10), fuel cell unit (1) or fuel cell system, wherein
a cell monitoring method according to claim 1 can be carried out and/or is carried out by the cell monitoring process, the fuel cell unit (1) or the fuel cell system.
